(19) United States
(12) Patent Application Publication
(10) Pub. No.: US 2001/0014534 A1
(43) Pub. Date: Aug. 16, 2001

(54) Stripper composition and stripping method

(75) Inventors: Hidemitsu Aoki, Tokyo (JP); Kenichi Nakabeppu, Tokyo (JP); Tatsuya Koito, Tokyo (JP)

Correspondence Address: Patent Group, Hutchins, Wheeler & Dittmar, 101 Federal Street, Boston, MA, 02110, US

(73) Assignee: NEC Corporation

(21) Appl. No.: 09/766,896

(22) Filed: Jan. 22, 2001

(30) Foreign Application Priority Data
Jan. 25, 2000 (JP) 2000-015601

(51) Int. Cl. H01L 21/461

(52) U.S. Cl. 438/689

(57) ABSTRACT

A stripper composition containing an anticorrosive agent containing, as essential components, (a) urea or a urea derivative and (b) a hydroxy aromatic compound.

### BACKGROUND OF THE INVENTION

1. Field of the Invention

The present invention relates to a stripper composition used for stripper unnecessary substances on a semiconductor substrate, for example, a resist film and an etching residue present after dry etching of an insulating film; as well as to a stripping method.

2. Description of the Related Art

In the process for production of a semiconductor device, formation of throughholes, wiring grooves, etc. are conducted using lithography, ordinarily by forming a resist film, conducting dry etching with the resist film being used as a mask, and removing the resist film. This removal of the resist film is conducted generally by plasma ashing and subsequent wet treatment using a stripper solution. With respect to the stripper solution, various stripper solutions have heretofore been developed; and there are known, for example, an organic sulfonic acid-based stripper solution containing an alkylbenzenesulfonic acid as a main component, an organic amine-based stripper solution containing an organic amine (e.g. monoethanolamine) as a main component, and a hydrofluoric acid-based stripper solution containing hydrofluoric acid as a main component.

Meanwhile, in recent years, as the speed requirement for semiconductor components has become higher, low-resistance materials (e.g. copper) have come to be used as a material for wring. Copper, as compared with conventional wiring materials (e.g. aluminum) is inferior in corrosion resistance to chemical solutions and is easily corroded during the stripping step. Hence, it has become necessary that the stripper solution used has corrosion inhibitability to the wiring material used.

JP-A-7-247498 discloses a technique for preventing a metal film formed on a semiconductor substrate, from being corroded, that is, a technique of using, as a cleaning solution after ashing, an aqueous solution containing a quaternary ammonium hydroxide, a saccharide or a sugaralcohol, and a urea compound to prevent an aluminum alloy from being corroded. The literatures shows, as a specific cleaning solution, a cleaning solution consisting of tetramethylammonium hydroxide, sorbitol, urea and water. In forming wirings using an aluminum alloy film containing aluminum as a main component, a process is employed which comprises forming a photoresist film having a desired pattern, on an aluminum alloy film and then dry-etching the aluminum alloy film with the photoresist being used as a mask. After the dry-etching, there is formed, on the side wall of the aluminum alloy film, a side wall-protective film which is a reaction product between the photoresist and the dry-etching gas used. Since there is generally used, as the dry-etching gas, a chlorine-based gas, chlorine is trapped into the side wall-protective film and, as a result, there has been a problem that the aluminum alloy film is corroded after the etching. With the technique of JP-A-7-247498, the side wall-protective film containing chlorine is thought to be effectively removed by using the above-mentioned cleaning solution having a particular composition. The above technique aims at effective removal of the side wall-protective film containing chlorine (this chlorine invites corrosion of the aluminum alloy film) and improves the stripping-ability of resist-stripper solution; however, the technique does not provide an anticorrosive agent capable of effectively preventing a corrodible metal (e.g. copper) from being corroded.

A resist-stripper solution containing an anticorrosive agent is disclosed in, for example, JP-A-8-334905. The literature shows, as examples of the anticorrosive agent, aromatic hydroxy compounds such as catechol, pyrogallol, hdyroxybenzoic acid and the like; and carboxyl group-containing organic compounds such as acetic acid, citric acid, succinic acid and the like. These anticorrosive agents, however, are for corrosion inhibition for aluminum-copper alloys containing aluminum as a main component, and have shown no sufficient corrosion inhibition action for highly corrodible copper.

In the above JP-A-334905, benztriazole (BTA) and derivatives thereof are disclosed as other anticorrosive agents. With these anticorrosive agents, certain corrosion inhibition action is obtained even for corrodible metals such as copper and the like.

### SUMMARY OF THE INVENTION

The anticorrosive agent containing BTA or a derivative thereof as a main component, however, are difficult to subject to biodegradation treatment and the waste liquid containing this anticorrosive agent has been difficult to dispose.

In recent years, the requirement for low environmental load has become increasingly strong and the safety requirement for waste liquid from plant of semiconductor device has become higher. These waste liquids are ordinarily decomposed by biological treatment (hereinafter referred to as “biodegradation treatment”). The above-mentioned BTA and derivatives thereof are difficult to subject to biodegradation treatment.

Therefore, in using a stripper solution containing BTA or a derivative thereof, the waste liquid generated therefrom has inevitably been disposed by a method other than the biodegradation treatment, requiring a higher cost and more labor.

In view of the above situation, the present invention aims at providing a stripper composition which can effectively strip and remove a resist film and an etching residue while preventing a corrodible metal (e.g. copper) from being corroded and which can be subjected to biodegradation treatment and allows easy disposal of waste liquid.

Development of an anticorrosive agent contained in a resist-stripper solution has heretofore been conducted with a primary objective of allowing the anticorrosive agent to have improved corrosion inhibitability to materials for wirings. In order to allow the anticorrosive agent to further have excellent biodegradability in addition to the corrosion inhibitability, a study must be made from a standpoint different from conventional standpoints. The present inventors made a study from such a standpoint and found out that both high corrosion inhibitability and excellent biodegradability can be achieved by using an anticorrosive agent containing a combination of two kinds of compounds. The present invention has been completed based on the above finding.

According to the present invention, there is provided a stripper composition containing an anticorrosive agent which contains (a) urea or a urea derivative and (b) a hydroxy aromatic compound, as essential components.

According to the present invention, there is also provided an above mentioned stripper composition, further comprising:

(c) a hydroxylamine or an alkanolamine, and

(d) water.

According to the present invention, there is also provided a stripping method which comprises stripping a resist film and/or an etching residue on a semiconductor wafer having an exposed metal film, by using an above mentioned stripper composition.

According to the present invention, there is also provided a stripping method which comprises:

forming, on a semiconductor wafer, a metal film and an insulating film in this order;

forming a resist film thereon;

conducting dry etching with the resist film being used as a mask, to form, in the insulating film, dents reaching the metal film; then

stripping the resist film and/or the residue of etching by using an above mentioned stripper composition.

According to the present invention, there is also provided a stripping method which comprises:

forming, on a semiconductor wafer, a metal film, a first insulating film and a second insulating film having desired openings;

conducting dry etching with the second insulating film being used as a mask, to form, in the first insulating film, dents reaching the metal film; then

stripping the residue of etching by using an above mentioned stripper composition.

Hydroxy aromatic compounds have heretofore been used as an anticorrosive agent for aluminum alloy film. However, these hydroxy aromatic compounds show no sufficient corrosion inhibition effect to corrodible metals such as copper when used by themselves. By using a hydroxy aromatic compound in combination with a urea derivative which is ordinarily not used as an anticorrosive agent, there is obtained an excellent corrosion inhibition action which is not obtainable only with either of the hydroxy aromatic compound and the urea derivative.

The reason therefor is not clear but is presumed to be as follows. A hydroxy aromatic compound is adsorbed on the surface of a metal (e.g. copper) film via the hydroxyl group or the like. At this time, the aromatic ring (which is hydrophobic) is at an exterior site; therefore, the metal surface becomes hydrophobic; as a result, copper is prevented from being corroded. Only with this hydroxy aromatic compound, however, it is difficult to cover all the metal surface sufficiently and densely. Meanwhile, urea or a urea derivative (hereinafter referred to as “urea type compound” as necessary) has, in the molecule, two nitrogen atoms showing an chelating action to a metal film and moreover has a relatively low molecular weight; therefore, is strongly adsorbed on the metal surface to form a dense coating layer. Moreover, since having high solubility in water, the urea type compound can be used in a large amount in an aqueous stripper solution. Therefore, when a hydroxy aromatic compound and a urea type compound are used in combination, they act toward a metal film surface so as to supplement each other, and impart hydrophobicity to a metal surface and form a dense coating layer. As a result, an excellent corrosion inhibition action which has been unobtainable heretofore, can be obtained.

Each urea type compound has a structure similar to those of urea, etc. (existing as a natural product in nature) and is very easily decomposed by organisms. Each hydroxy aromatic compound has good biodegradability as well. Therefore, the anticorrosive agent of the present invention has good biodegradability.

### BRIEF DESCRIPTION OF THE DRAWINGS

FIG. 1 shows sectional views for explaining the steps for forming a through hole.

FIG. 2 shows sectional views for explaining the steps for forming a through hole.

FIG. 3 is a graph showing the effect of urea concentration on the etching rate of copper film.

FIG. 4 is a graph showing the effect of gallic acid concentration on the etching rate of copper film.

### DETAILED DESCRIPTION OF THE PREFFERED EMBODYMENTS

The component (a) of the present invention is urea or a urea derivative. As specific examples of the component (a), there can be mentioned urea, 1,1-dimethylurea, 1,3-dimethylurea, 1,1,3-trimethylurea, 1,1,3,3-tetramethylurea, thiourea, 1,1-dimethylthiourea, 1,3-dimethylthiourea, 1,1,3-trimethylthiourea, 1,1,3,3-tetramethylthiourea, ethyleneurea and ethylenethiourea. At least one kind of these compounds can be selected.

The component (a) of the present invention is preferably a compound represented by the following general formula (1):

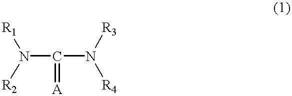

(R₁, R₂, R₃ and R₄ are each independently a hydrogen atom or an alkyl group having 1 to 3 carbon atoms; and A is an oxygen atom or a sulfur atom). The urea type compound having the above structure shows very good corrosion inhibitability because it forms a strong and dense coating layer on the surface of a metal. Moreover, the urea type compound has excellent biodegradability because it has a structure similar to that of urea existing in nature. Of the compounds of the above structure, urea, in particular, has a low molecular weight, has very high solubility in water and can be dissolved in a stripper composition in a large amount, and therefore has excellent corrosion inhibitability; moreover, has very good biodegradability.

In the present invention, the lower limit of the amount of the component (a) used is preferably 1% by mass, particularly preferably 5% by mass. By using the component (a) in such an amount, very good corrosion inhibitability can be obtained. As to the upper limit, there is no particular restriction; however, the upper limit can be, for example, about 60% by mass from the standpoint of the solubility of component (a) in stripper solution.

The component (b) of the present invention is a hydroxy aromatic compound. As specific examples of the hydroxy aromatic compound, there can be mentioned phenol, cresol, xylenol, p-aminophenol, m-aminophenol, diaminophenol, p-hydroxybenzoic acid, o-hydroxybenzoic acid, catechol, resorcinol, hydroquinone, salicylic alcohol, p-hydroxybenzyl alcohol, o-hydroxybenzyl alcohol, p-hydroxyphenethyl alcohol, 2,4-dihydroxybenzoic acid, 2,5-dihydroxybenzoic acid, 3,4-dihydroxybenzoic acid, 3,5-dihydroxybenzoic acid, pyrogallol, hydroxyhydroquinone, fluoroglucinol, gallic acid and tannic acid. The methyl esters and ethyl esters of the above benzoic acids, gallic acid and tannic acid can also be used. These compounds can be used singly or in combination of two or more kinds.

Of these, a benzene derivative having, in the molecule, at least two phenolic hydroxyl groups is selected preferably. Such a compound is easily adsorbed on a metal, and is easily soluble in water and therefore can be used in a large amount in an aqueous stripper solution; as a result, can show good corrosion inhibitability. As examples of the benzene derivative having at least two phenolic hydroxyl groups in the molecule, there can be mentioned catechol, resorcinol, hydroquinone, pyrogallol, hydroxyhydroquinone, fluoroglucinol, gallic acid and tannic acid. Of these, preferred are pyrogallol, hydroxyhydroquinone, fluoroglucinol, gallic acid and tannic acid; particularly preferred are gallic acid and pyrogallol. It is because they show particularly high corrosion inhibitability and biodegradability. These compounds may be used singly or in combination of two or more kinds.

In the present invention, the upper limit of the amount of the component (b) used is preferably 20% by mass, particularly preferably 10% by mass. The lower limit is preferably 0.1% by mass, particularly preferably 1% by mass. By using the component (b) in such an amount, very good corrosion inhibitability can be obtained.

In the present invention, the component (c) is a hydroxylamine or an alkanolamine.

Specific examples of the hydroxylamine include hydroxylamine (NH₂OH), N-methylhydroxylamine, N,N-dimethylhydroxylamine and N,N-diethylhdyroxylamine.

Specific examples of the alkanolamine include monoethanolamine, diethanolamine, N-ethylaminoethanol, N-methylaminoethanol, dimethylaminoethanol and 2-(2-aminoethoxy)ethanol. Of these, monoethanolamine and N-methylaminoethanol are particularly preferred.

In the present invention, the upper limit of the amount of the component (c) is preferably 70% by mass, particularly preferably 60% by mass. The lower limit is preferably 5% by mass, particularly preferably 10% by mass. By containing the component (c) in such an amount, the present stripper composition can remove resist film and etching residue very efficiently while maintaining good corrosion inhibitability.

The upper limit of the amount of water [which is the component (d)] is preferably 40% by mass, particularly preferably 30% by mass. The lower limit is preferably 2% by mass, particularly preferably 5% by mass. By containing water in such an amount, the function of the stripper component, i.e. the hydroxylamine or alkanolamine (c) is exhibited sufficiently, and the stripping-ability and corrosion inhibitability of the present stripper composition become very good.

The present stripper composition may further contain, as a component (e), a water-soluble organic solvent, in addition to the above-mentioned components (a) to (d). As the water-soluble organic solvent, there can be used an organic solvent miscible with water and the other components of the present invention.

As such a water-soluble organic solvent, there can be mentioned sulfoxides such as dimethyl sulfoxide and the like; sulfones such as dimethylsulfone, diethylsulfone, bis(2-hydroxyethyl)sulfone, tetramethylenesulfone and the like; amides such as N,N-dimethylformamide, N-methylformamide, N,N-dimethylacetamide, N-methylacetamide, N,N-diethylacetamide and the like; lactams such as N-methyl-2-pyrrolidone, N-ethyl-2-pyrrolidone, N-propyl-2-pyrrolidone, N-hydroxymethyl-2-pyrrolidone, N-hydroxyethyl-2-pyrrolidone and the like; imidazolidinones such as 1,3-dimethyl-2-imidazolidinone, 1,3-diethyl-2-imidazolidinone, 1,3-diisopropyl-2-imidazolidinone and the like; lactones such as γ-butyrolactone, δ-valerolactone and the like; and polyhydric alcohols and derivatives thereof, such as ethylene glycol, ethylene glycol monomethyl ether, ethylene glycol monoethyl ether, ethylene glycol monobutyl ether, ethylene glycol monomethyl ether acetate, ethylene glycol monoethyl ether acetate, diethylene glycol, diethylene glycol monomethyl ether, diethylene glycol monoethyl ether, diethylene glycol monobutyl ether and the like. These compounds can be used singly or in combination of two or more kinds. Of these, preferred are dimethyl sulfoxide, N,N-dimethylformamide, N,N-dimethylacetamide, N-mehtyl-2-pyrrolidone, 1,3-dimethyl-2-imidazolidinone, ethylene glycol and diethylene glycol monobutyl ether for their excellent stripping-ability. Particularly preferred are dimethyl sulfoxide for the excellent corrosion inhibitability for substrate.

In the present invention, the upper limit of the amount of the component (e), i.e. the water-soluble organic solvent is preferably 80% by mass, particularly preferably 70% by mass. The lower limit is preferably 5% by mass, particularly preferably 10% by mass. By containing the water-soluble organic solvent in such an amount, the present stripper composition can have a very good balance between stripping-ability and corrosion inhibitability.

The stripper composition of the present invention may contain only the components (a) to (d) or only the components (a) to (e), or may further contain other component as necessary as long as the properties of the present stripper composition are not impaired. For example, a stripper component such as organic amine, hydrofluoric acid salt or the like may be added in addition to the above-mentioned components.

The stripper composition of the present invention can be used for stripper of various resists. For example, it can be used for (i) a positive resist containing a naphthoquinone diazide compound and a novolac resin, (ii) a positive resist containing a compound capable of generating an acid upon light exposure, a compound which is decomposed by an acid and comes to have increased solubility in an aqueous alkali solution, and an alkali-soluble resin, (iii) a positive resist containing a compound capable of generating an acid upon light exposure, and an alkali-soluble resin having a group which is decomposed by an acid and comes to have increased solubility in an aqueous alkali solution, and (iv) a negative resist containing a compound capable of generating an acid upon light exposure, a crosslinking agent and an alkali-soluble resin.

The substances to be stripped or removed by the present stripper composition are unnecessary substances remaining on a semiconductor substrate. The unnecessary substances on semiconductor substrate refer to various unnecessary substances generated during the process for production of semiconductor device, and include resist film, etching residue after dry etching, chemically modified resist film, etc. The present stripper composition is more effective particularly when the substances to be stripped or removed are a resist film and/or an etching residue on a semiconductor substrate having an exposed surface of a metal film. The present stripper composition exhibits its corrosion inhibition action more effectively when the above metal film is a copper film.

Next, there is described, as an example of applying the stripper composition of the present invention, a case of forming an interconnection plug on a copper wiring by a single damascene process.

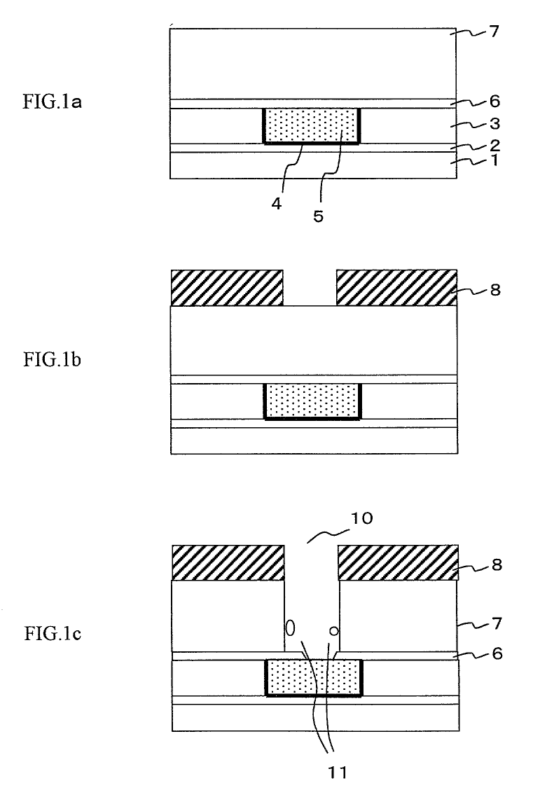

First, as shown in FIG. 1(a), on a semiconductor substrate (not shown) having devices such as transistors and the like are formed a silicon oxide film 1, a silicon nitride film 2 and a silicon oxide film 3; then, a barrier metal film 4 and a copper wiring consisting of a copper film 5 are formed by a known damascene process using chemical mechanical polishing (hereinafter referred to as CMP); thereon are formed a silicon nitride film 6 having a thickness of about 50 to 100 nm and a silicon oxide film 7 having a thickness of about 600 to 1,000 nm. The thickness of the copper film 5 can be determined as desired but is set preferably at, for example, 350 nm or less for lower parasitic capacity between neighboring wirings. When the thickness of the copper wiring is small, the thickness of the corroded copper layer is large relative to the total thickness of the copper wiring layer and an increase in the resistance of copper wiring caused by the corrosion of copper surface becomes a problem. However, use of the stripper composition of the present invention can solve such a problem and makes possible a copper wiring having a small thickness. Incidentally, in the present example, the thickness of the silicon nitride film 6 is about 50 to 100 nm, but it may be made larger for higher etching preventability.

Next, on the silicon oxide film 7 is formed a resist film 8 having a desired pattern [FIG. 1(b)].

Next, the silicon oxide film 7 is dry-etched using the resist film 8 as a mask, until the silicon nitride film 6 is exposed [FIG. 1(c)]. At this time, an etching residue 11 sticks to the inner wall of a through hole 10. The diameter of the through hole is, for example, about 0.2 μm. As the etching gas, there is preferably used a gas which can etch the silicon oxide film faster than the silicon nitride film.

The silicon nitride film 6 has a function for prevention of copper diffusion and also a function for prevention of copper etching. However, as shown in FIG. 1(c), there arise cases that dry etching cannot be terminated on the silicon nitride film 6 as intended. This is for the following reason. Generally in a process such as the present example, through holes of various diameters are formed on a semiconductor wafer. In the through holes of small diameters, etching proceeds slowly owing to the microloading effect. Therefore, a certain longer time is needed for etching in order to form through holes. Thereby, the silicon nitride film 6 is etched in some throughholes, allowing part of the copper film 5 to be exposed. Also, when, for example, a dent called dishing is generated on the copper film 5, the silicon nitride film 6 comes to have a thin film portion; this portion of the silicon nitride film 6 is etched and part of the copper film 5 may be exposed. Exposure of the copper film 5 can be prevented if the silicon nitride film 6 is formed in a large thickness in the step of FIG. 1(a); however, if it is done, the capacity between neighboring copper wirings becomes large and the high-speed operation of the semiconductor device obtained tends to be impaired.

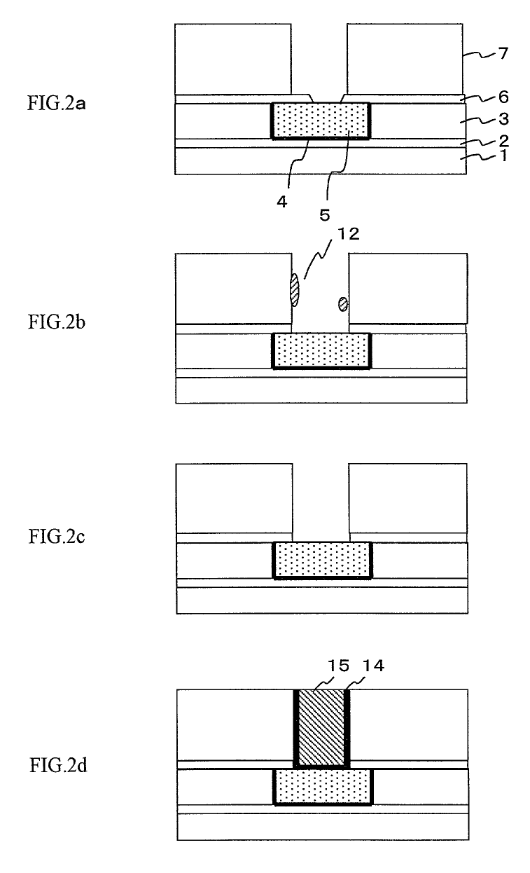

After the completion of the etching, oxygen plasma ashing is conducted to remove part of the resist film 8. Then, a stripping treatment is conducted using the stripper composition of the present invention. By this stripping treatment are removed the resist film which cannot be sufficiently removed by the ashing and the residue 11 of etching. As mentioned previously, the copper film 5 is exposed in at least some through holes, after the etching; therefore, the stripper composition needs to have corrosion inhibitability for copper. By using the stripper composition containing the components (a) and (b), the resist film and the etching residue 11 can be removed effectively without damaging the copper film 5. A state after the stripping treatment is shown in FIG. 2(a).

Then, a different etching gas is used and etching of the silicon nitride film 6 is conducted. At this time, an etching residue 12 sticks to the inner wall of the through hole 10 [FIG. 2(b)]. In order to strip and remove the etching residue 12, a stripping treatment is conducted again using the above-mentioned stripper composition. At the stage of this stripping treatment, the copper film 5 is exposed at the bottom of the through hole 10; however, by using the stripper composition containing the components (a) and (b), the etching residue 12 can be removed without damaging the copper film 5 [FIG. 2(c)].

Then, a barrier metal film 14 (which is a laminate of Ti and TiN in this order) and a tungsten film 15 are formed inside the through hole; thereafter, leveling is made by CMP; thereby, an interconnection plug can be formed [FIG. 2(d)].

### EXAMPLE 1

This is an example in which a stripper composition of the present invention was applied to a process for forming through holes on copper wirings.

Samples were produced by carrying out the above-mentioned process described in FIG. 1 to FIG. 2(c). The procedure used for sample production is explained below.

First, copper wirings were formed on a silicon wafer. Thereon were formed a silicon nitride film (thickness: 90 nm) and a silicon oxide film (thickness: 900 nm), each by plasma CVD. Then, a positive resist film was formed by spinner coating. As the material for the resist film, there was used PEX4 (a product of Tokyo Ohka Kogyo Co., Ltd.) which was a positive resist material for KrF. The resist film was exposed to a light via a mask pattern, followed by development with an aqueous tetramethylammonium hydroxide solution, to obtain a resist pattern.

Using this resist pattern as a mask, the silicon oxide film was dry-etched until the silicon nitride film was exposed, to form through holes having a diameter of 0.2 μm. As the etching gas, a fluorocarbon type gas was used. After the completion of the etching, oxygen plasma ashing was conducted to remove part of the resist pattern. Thereafter, a stripping treatment was conducted using a stripper composition shown in No. 1 of Table 1.

Next, the silicon nitride film was etched using a different etching gas, to expose each copper wiring at the bottom of each through hole. In order to remove the etching residue generated in the above etching, a stripping treatment was conducted again using the same stripper composition (No. 1 in Table 1) as used above.

The same procedure as above was conducted using each of stripper compositions Nos. 2 to 8 shown in Table 1, to produce total 8 kinds of samples.

Each sample (wafer) obtained above was rinsed with pure water, and its section was observed by a scanning electron microscope (SEM) to examine (1) stripping-ability of resist film and etching residue and (2) corrosion inhibitability for copper film. The following rating standards were used.

Stripping-ability

The degree of remaining of resist film and etching residue was examined visually and rated by the following three grades.

◯: Substantially no remaining

Δ: Remaining in a small amount

x: Remaining in a large amount

Corrosion inhibitability

The corrosion status of copper film surface was examined visually and rated by the following four grades.

⊚: Copper film had no corrosion.

◯: Copper film had slight corrosion.

Δ: Copper film had corrosion.

x: Copper film had striking corrosion.

TABLE 1

| No. of | Formulation of stripper composition | | | Rating | |
|---|---|---|---|---|---|
| Stripper | Anticorrosive agent | Stripper agent | | Striping- | Corrosion |
| composition | (mass %) | (mass %) | Water | ability | inhibitability |
| 1 | Gallic acid (5) | NMEA (60) | Remainder | ◯ | ◯ |
| | Urea (5) | | | | |
| 2 | Gallic acid (5) | NMEA (60) | Remainder | ◯ | ⊚ |
| | Urea (25) | | | | |
| 3 | Pyrogallol (5) | NMEA (60) | Remainder | ◯ | ⊚ |
| | Urea (25) | | | | |
| 4 | Gallic acid (5) | MEA (60) | Remainder | ◯ | ⊚ |
| | Urea (25) | | | | |
| 5 | Catechol (5) | NMEA (60) | Remainder | ◯ | ◯ |
| | Urea (25) | | | | |
| 6 | Urea (25) | NMEA (60) | Remainder | ◯ | x |
| 7 | Gallic acid (5) | NMEA (60) | Remainder | ◯ | x |
| 8 | Sorbitol (5) | NMEA (60) | Remainder | ◯ | x |
| | Urea (25) | | | | |

*1 In the column of water, “remainder” refers to a remainder after the amounts of anticorrosive agent and stripper agent have been subtracted from 100% by mass.

*2 NMEA: N-methylethanolamine MEA: monoethanolamine

As is clear from the above, each stripper composition of the present invention has excellent stripping-ability and corrosion inhibitability. In the present example, the present invention was applied to a single damascene process; however, the present invention can also be applied to a dual damascene process.

### EXAMPLE 2

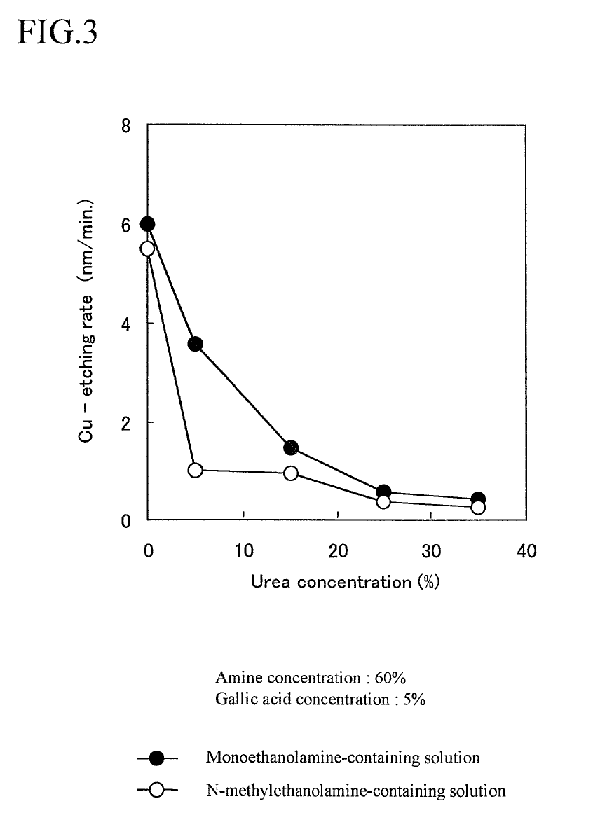

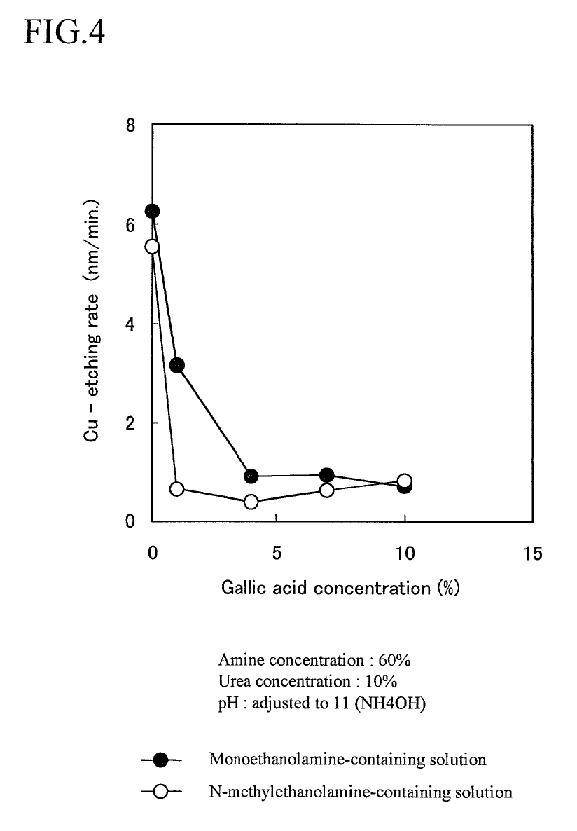

A silicon wafer having a copper film on the whole surface was immersed in various given stripper solutions at 80° C. for 10 minutes. The etching rate of copper in each solution was measured from the thicknesses of the copper films before and after immersion. The results are shown in FIG. 3 and FIG. 4.

The stripper solutions in FIG. 3 had the following compositions.

Amine; 60% by mass

Gallic acid: 5% by mass

Urea: 0, 5, 15, 25 or 35% by mass

Water: remainder

The stripper solutions in FIG. 4 had the following compositions. Incidentally, ammonia water was added in order to remove the factor of pH variation caused by the difference in addition amount of gallic acid, whereby the pH of each stripper solution was controlled to 11.

Amine: 60% by mass

Gallic acid: 0, 1, 4, 7 or 10% by mass

Urea: 10% by mass

Water: remainder

As the amine, there was used NMEA (N-methylethanolamine) or MEA (monoethanolamine).

When the etching rate shown by the ordinate of FIG. 3 or 4 exceeded 4 nm/min, the corrosion of copper film became striking. As is clear from FIGS. 3 and 4, combined use of urea and gallic acid shows excellent corrosion inhibitability.

### EXAMPLE 3

Test compounds shown in Table 2 were measured for biodegradability according to the OECD method [described in pp. 230 to 232 of “Experimental Method by Environmental Microorganisms (Kodansha Scientific (1988) edited by Ryuichi Sudo)]. That is, each test compound was added to a liquid culture medium containing a particular microorganism, and the mixture was stored at 25° C. and measured for the decomposition percent of the test compound at the initial day and after 7, 14, 21 or 28 days. The decomposition percent of each test compound after 28 days was rated according to the following standard.

⊚: Biodegradability is 80% or more.

◯: Biodegradability is 30% to less than 80%.

Δ: Biodegradability is 5% to less than 30%.

x: Biodegradability is less than 5%.

The results of rating are shown in Table 2.

TABLE 2

| Test compound | Biodegradability |
|---|---|
| Urea | ⊚ |
| Pyrogallol | ◯ |
| Gallic acid | ◯ |
| Benztriazole | X |

As described above, since the stripper composition of the present invention contains an anticorrosive agent containing particular components, the composition can effectively strip and remove resist film and etching residue while preventing corrodible metals (e.g. copper) from being corroded, and moreover is biodegradable (this allows easy disposal of the waste liquid generated). Therefore, the present stripper composition is preferably applicable to, for example, a process for production of a semiconductor device containing copper wirings.

This application is based on applications NO. 2000-15601 filed in Japan, the content of which is incorporated hereinto by reference.

What is claimed is:

1. A stripper composition containing an anticorrosive agent which contains (a) urea or a urea derivative and (b) a hydroxy aromatic compound, as essential components.

2. A stripper composition according to claim 1, further comprising:
(c) a hydroxylamine or an alkanolamine, and
(d) water.

3. A stripper composition according to claim 2, wherein the amounts of the components (a), (b), (c) and (d) are 1 to 60% by mass, 0.1 to 20% by mass, 5 to 70% by mass and 2 to 40% by mass, respectively.

4. A stripper composition according to claim 1, wherein the component (a) is a compound represented by the following general formula (1): 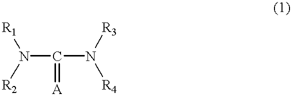
(R₁, R₂, R₃ and R₄ are each independently a hydrogen atom or an alkyl group having 1 to 3 carbon atoms; and A is an oxygen atom or a sulfur atom).

5. A stripper composition according to claim 1, wherein the component (b) is a benzene derivative having at least two phenolic hydroxyl groups in the molecule.

6. A stripper composition according to claim 5, wherein the component (b) is at least one compound selected from the group consisting of pyrogallol, hydroxyhydroquinone, fluoroglucinol, gallic acid and tannic acid.

7. A stripper composition according to claim 1, removing a resist film and/or an etching residue on a semiconductor substrate having an exposed metal film.

8. A stripper composition according to claim 7, wherein the metal film is a copper film.

9. A stripping method which comprises stripping a resist film and/or an etching residue on a semiconductor wafer having an exposed metal film, by using a stripper composition according to claim 1.

10. A stripping method which comprises stripping a resist film and/or an etching residue on a semiconductor wafer having an exposed metal film, by using a stripper composition according to claim 2.

11. A stripping method which comprises stripping a resist film and/or an etching residue on a semiconductor wafer having an exposed metal film, by using a stripper composition according to claim 3.

12. A stripping method which comprises stripping a resist film and/or an etching residue on a semiconductor wafer having an exposed metal film, by using a stripper composition according to claim 4.

13. A stripping method which comprises stripping a resist film and/or an etching residue on a semiconductor wafer having an exposed metal film, by using a stripper composition according to claim 5.

14. A stripping method which comprises stripping a resist film and/or an etching residue on a semiconductor wafer having an exposed metal film, by using a stripper composition according to claim 6.

15. A stripping method which comprises:
forming, on a semiconductor wafer, a metal film and an insulating film in this order;
forming a resist film thereon;
conducting dry etching with the resist film being used as a mask, to form, in the insulating film, dents reaching the metal film; then
stripping the resist film and/or the residue of etching by using a stripper composition according to claim 1.

16. A stripping method which comprises:
forming, on a semiconductor wafer, a metal film and an insulating film in this order;
forming a resist film thereon;
conducting dry etching with the resist film being used as a mask, to form, in the insulating film, dents reaching the metal film; then
stripping the resist film and/or the residue of etching by using a stripper composition according to claim 2.

17. A stripping method which comprises:
forming, on a semiconductor wafer, a metal film and an insulating film in this order;
forming a resist film thereon;
conducting dry etching with the resist film being used as a mask, to form, in the insulating film, dents reaching the metal film; then
stripping the resist film and/or the residue of etching by using a stripper composition according to claim 3.

18. A stripping method which comprises:
forming, on a semiconductor wafer, a metal film and an insulating film in this order;
forming a resist film thereon;
conducting dry etching with the resist film being used as a mask, to form, in the insulating film, dents reaching the metal film; then
stripping the resist film and/or the residue of etching by using a stripper composition according to claim 4.

19. A stripping method which comprises:
forming, on a semiconductor wafer, a metal film and an insulating film in this order;
forming a resist film thereon;
conducting dry etching with the resist film being used as a mask, to form, in the insulating film, dents reaching the metal film; then
stripping the resist film and/or the residue of etching by using a stripper composition according to claim 5.

20. A stripping method which comprises:
forming, on a semiconductor wafer, a metal film and an insulating film in this order;
forming a resist film thereon;
conducting dry etching with the resist film being used as a mask, to form, in the insulating film, dents reaching the metal film; then
stripping the resist film and/or the residue of etching by using a stripper composition according to claim 6.

21. A stripping method which comprises:
forming, on a semiconductor wafer, a metal film, a first insulating film and a second insulating film having desired openings;
conducting dry etching with the second insulating film being used as a mask, to form, in the first insulating film, dents reaching the metal film; then
stripping the residue of etching by using a stripper composition according to claim 1.

22. A stripping method which comprises:
forming, on a semiconductor wafer, a metal film, a first insulating film and a second insulating film having desired openings;
conducting dry etching with the second insulating film being used as a mask, to form, in the first insulating film, dents reaching the metal film; then
stripping the residue of etching by using a stripper composition according to claim 2.

23. A stripping method which comprises:
forming, on a semiconductor wafer, a metal film, a first insulating film and a second insulating film having desired openings;
conducting dry etching with the second insulating film being used as a mask, to form, in the first insulating film, dents reaching the metal film; then
stripping the residue of etching by using a stripper composition according to claim 3.

24. A stripping method which comprises:
forming, on a semiconductor wafer, a metal film, a first insulating film and a second insulating film having desired openings;
conducting dry etching with the second insulating film being used as a mask, to form, in the first insulating film, dents reaching the metal film; then
stripping the residue of etching by using a stripper composition according to claim 4.

25. A stripping method which comprises:
forming, on a semiconductor wafer, a metal film, a first insulating film and a second insulating film having desired openings;
conducting dry etching with the second insulating film being used as a mask, to form, in the first insulating film, dents reaching the metal film; then
stripping the residue of etching by using a stripper composition according to claim 5.

26. A stripping method which comprises:
forming, on a semiconductor wafer, a metal film, a first insulating film and a second insulating film having desired openings;
conducting dry etching with the second insulating film being used as a mask, to form, in the first insulating film, dents reaching the metal film; then
stripping the residue of etching by using a stripper composition according to claim 6.

27. A stripping method according to claim 9, wherein the metal film is a copper film.

28. A stripping method according to claim 10, wherein the metal film is a copper film.

29. A stripping method according to claim 11, wherein the metal film is a copper film.
